(19) United States
(12) Patent Application Publication
(10) Pub. No.: US 2012/0279684 A1
(43) Pub. Date: Nov. 8, 2012

(54) SYSTEMS AND METHODS FOR COOLING ELECTRONIC EQUIPMENT

(76) Inventors: Earl Keisling, Ridgefield, CT (US); John Costakis, Hyde Park, NY (US); Gerald McDonnell, Poughquag, NY (US)

(21) Appl. No.: 13/517,089

(22) PCT Filed: Jul. 13, 2011
(86) PCT No.: PCT/US11/43893

§ 371 Date: Jun. 19, 2012

(30) Foreign Application Priority Data
Jul. 31, 2010 (US) 61363723

(51) Int. Cl. G06F 1/20; F25B 39/02; H05K 7/20

(52) U.S. Cl. 165/80.2; 62/259.2; 62/526

(57) ABSTRACT

A system for cooling electronic equipment includes first and second heat exchangers and a condenser. The first exchanger is disposed in an airflow in thermal communication with electronic equipment and is configured to receive a cooling fluid at a first temperature. The first exchanger enables heat transfer from the airflow to the cooling fluid to heat the cooling fluid to a second temperature. The second exchanger is disposed in the airflow between the first exchanger and the electronic equipment and is configured to receive the cooling fluid at the second temperature. The second exchanger enables heat transfer from the airflow to the cooling fluid to heat the cooling fluid to a third temperature. The condenser is configured to receive the cooling fluid at the third temperature and is configured to enable heat transfer from the cooling fluid to a cooling source to cool the cooling fluid to the first temperature.

### CROSS-REFERENCE TO RELATED APPLICATIONS

This application claims priority to, and the benefit of, U.S. Provisional Patent Application No. 61/363,723, filed on Jul. 13, 2010, the entire contents of which are incorporated by reference herein.

### BACKGROUND

1. Technical Field

The present disclosure relates generally to cooling systems and methods and, more particularly, to cooling systems and methods for cooling electronic equipment, including computer servers disposed in high-density data centers.

2. Background of Related Art

Over the past several years, computer equipment manufacturers have expanded the data collection and storage capabilities of their servers. However, as the data collection and storage capabilities of computer servers have increased, so to have total power consumption and total heat output per server increased. As a result, there is a continuing need for improved power and temperature control systems capable of handling the tremendous and continued growth in capacity of computer data collection and storage.

Cooling systems to date have been unable to keep pace with the increasing heat loads produced by servers, especially in high-density data centers. In an attempt to combat these increased heat loads (measured in kilowatts (kW)), data rooms have allocated additional space within the data rooms themselves to allow for a greater volume of cooling infrastructure. More recently, cooling systems have been designed to concentrate the cooling at the computer server racks, i.e., at the heat source. These cooling systems include rear-door heat exchangers and rack-top coolers.

Cooling systems, such as rear-door heat exchangers and rack-top coolers, circulate de-ionized water, R-134a (i.e., 1,1,1,2-Tetrafluoroethane) refrigerant, or other similar fluid in order to reject heat from server racks. However, spatial constraints limit the ability of these systems to adequately cool high density data centers. The output capacity of rear-door exchangers, for example, is limited by the physical size, i.e., the exterior dimensions, of the server rack, and the amount of fluid (measured in liters per second (l/s) or gallons per minute (gpm)) that can flow through the rear-door exchanger without excessive pressure drops. Typical rear-door heat exchangers can produce up to approximately 12-16 kW of concentrated cooling to computer server racks. Also, overhead, or rack-top coolers can produce up to 20 kW of cooling output using R-134a liquid refrigerant. However, the total capacity of these systems is limited by the physical size of the cooling coils as well as the size of the enclosure for the computer server rack. Moreover, these systems are currently unable to handle the cooling requirements of the more recently developed high-density computer servers, which can now produce heat outputs in excess of 35 kW.

### BRIEF DESCRIPTION OF THE DRAWINGS

Various embodiments of the present disclosure are described with reference to the accompanying drawings wherein:

FIG. 1 is a schematic diagram of a cooling system in accordance with one embodiment of the present disclosure;

FIG. 2 is an exploded, perspective view of a portion of the cooling system of FIG. 1 showing the general direction of air flow through first and second heat exchangers of the cooling system during operation;

FIG. 3 is a cut-away, perspective view of one embodiment of the first heat exchanger of FIG. 2;

FIG. 4A is a cross-sectional view of the second heat exchanger taken along section line 4A-4A of FIG. 1;

FIG. 4B is a cross-sectional view of another embodiment of the second heat exchanger;

FIG. 4C is a front view of another embodiment of a heat exchanger configured for use with the cooling system of FIG. 1;

FIG. 5A is a perspective view of another embodiment of a heat exchanger configured for use with the cooling system of FIG. 1;

FIG. 5B is a cross-sectional view of the heat exchanger of FIG. 5A taken along section line 5B-5B of FIG. 5A; and

FIG. 6 is a schematic diagram of another embodiment of a cooling system in accordance with the present disclosure.

### SUMMARY

In one aspect, the present disclosure features a system for cooling electronic equipment. The system generally includes a first heat exchanger, a second heat exchanger, and a condenser. The first heat exchanger has a fluid input and a fluid output and is configured to be disposed in an airflow path in thermal communication with electronic equipment. The fluid input of the first heat exchanger is configured to receive a cooling fluid at a first temperature. The first heat exchanger is configured to enable heat transfer from the airflow to the cooling fluid to heat the cooling fluid to a second temperature. The second heat exchanger has a fluid input and a fluid output. The fluid input of the second heat exchanger is in fluid communication with the fluid output of the first heat exchanger. The second heat exchanger is configured to be disposed in the airflow between the first heat exchanger and the electronic equipment. The fluid input of the second heat exchanger is configured to receive the cooling fluid at the second temperature from the fluid output of the first heat exchanger. The second heat exchanger enables heat transfer from the airflow to the cooling fluid to heat the cooling fluid to a third temperature.

The condenser has a fluid input and a fluid output. The fluid input of the condenser is in fluid communication with the fluid output of the second heat exchanger and the fluid output of the condenser is in fluid communication with the fluid input of the first heat exchanger. The fluid input of the condenser receives the cooling fluid at the third temperature from the fluid output of the second heat exchanger. The condenser enables heat transfer from the cooling fluid to a cooling source to cool the cooling fluid to the first temperature.

In some embodiments, the first heat exchanger is a micro-channel heat exchanger, although other suitable heat exchangers are contemplated. The second heat exchanger may be a flat-plate heat exchanger, a serpentine heat exchanger, or any other suitable heat exchanger.

In some embodiments, the second heat exchanger diffuses the airflow across the first heat exchanger.

In some embodiments, the condenser transforms the cooling fluid from a gas to a liquid, the first exchanger transforms the cooling fluid from a liquid to a liquid-gas mixture, and/or the second heat exchanger transforms the cooling fluid from a liquid-gas mixture to a gas.

In some embodiments, the first temperature is between about 18° Celsius and about 24° Celsius, the second temperature is between about 24° Celsius and about 32° Celsius, and the third temperature is between about 32° Celsius and about 41° Celsius.

In another aspect, the present disclosure features a method of cooling electronic equipment. The method generally includes passing a first cooling fluid through a first heat exchanger disposed in an airflow in thermal communication with electronic equipment to transform the first cooling fluid from a liquid to a liquid-gas mixture, passing the first cooling fluid through a second heat exchanger disposed in the airflow between the first heat exchanger and the electronic equipment to transform the first cooling fluid from the liquid-gas mixture to a gas, and condensing the first cooling fluid from a gas to a liquid by enabling heat transfer from the first cooling fluid to a second cooling fluid flowing through a cooling circuit.

In some embodiments, the first heat exchanger is a micro-channel heat exchanger, although other similar heat exchangers are contemplated. The second heat exchanger may be a flat-plate heat exchanger, a serpentine heat exchanger, or any other similar heat exchanger.

In some embodiments, the second heat exchanger diffuses the airflow across the first heat exchanger.

In some embodiments, passing the cooling fluid through the first heat exchanger includes heating the cooling fluid from a first temperature to a second temperature, passing the cooling fluid through the second heat exchanger includes heating the cooling fluid from the second temperature to a third temperature, and condensing the cooling fluid includes cooling the cooling fluid from the third temperature to the first temperature.

In yet another aspect, the present disclosure features a heat exchanger assembly. The heat exchanger generally includes a first heat exchanger and a second heat exchanger. The first heat exchanger is configured to be disposed in thermal communication with electronic equipment. The first heat exchanger is configured to receive cooling fluid in a liquid phase. The first heat exchanger is configured to transform the cooling fluid from the liquid phase to a liquid-gas mixture phase. The second heat exchanger is in thermal communication with the electronic equipment. The second heat exchanger is configured to receive the cooling fluid in the liquid-gas mixture phase. The second heat exchanger is configured to transform the cooling fluid from the liquid-gas mixture phase to a gas phase. In some embodiments, the first heat exchanger and the second heat exchanger are configured to be disposed in an airflow. In other embodiments, the second heat exchanger is configured to be disposed in the airflow upstream from the first heat exchanger.

In some embodiments, the first heat exchanger is a micro-channel heat exchanger, although other suitable heat exchangers are contemplated. In some embodiments, the second heat exchanger may be a flat-plate heat exchanger, a serpentine heat exchanger, or any other similar heat exchanger.

### DETAILED DESCRIPTION

Particular embodiments of the present disclosure are described below with reference to the accompanying drawings.

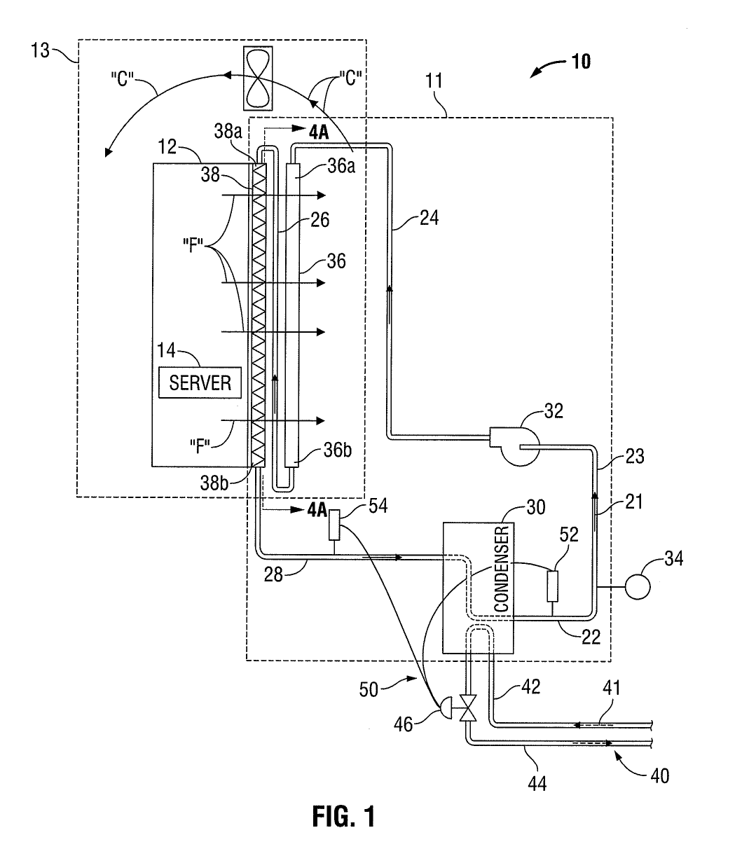

FIG. 1 is a schematic diagram of a cooling system 10 for electronic equipment. In the embodiment shown in FIG. 1, the cooling system 10 is configured for use in high-density data centers having one or more IT cabinets or server racks 12, each of which contains one or more servers 14. In other embodiments, however, the cooling system 10 may be configured for cooling any other electronic equipment or system. Cooling system 10 generally features a cooling circuit 11 including a condenser 30, a fluid pump 32, a liquid receiver 34, a heat exchanger assembly 35, and a feedback control assembly 50. The heat exchanger assembly 35 includes a first heat exchanger 36 and a second heat exchanger 38.

A fan 60 is also provided to facilitate the re-circulation of air through the heat exchanger assembly 35. A plurality of pipe segments interconnects the various components of cooling system 10. More specifically, pipe segment 22 interconnects condenser 30 and liquid receiver 34, pipe segment 23 interconnects liquid receiver 34 and fluid pump 32, pipe segment 24 interconnects fluid pump 32 and first heat exchanger 36, pipe segment 26 interconnects first heat exchanger 36 and second heat exchanger 38, and pipe segment 28 completes the cooling circuit 11 by connecting second heat exchanger 38 back to condenser 30. Feedback control assembly 50, as will be described below, includes a first temperature sensor 52 and a second temperature sensor 54 disposed on either side of condenser 30. The sensed temperatures from the first temperature sensor 52 and the second temperature sensor 54 are used to control the valve 46, which regulates the flow of cooling liquid through second cooling circuit 40.

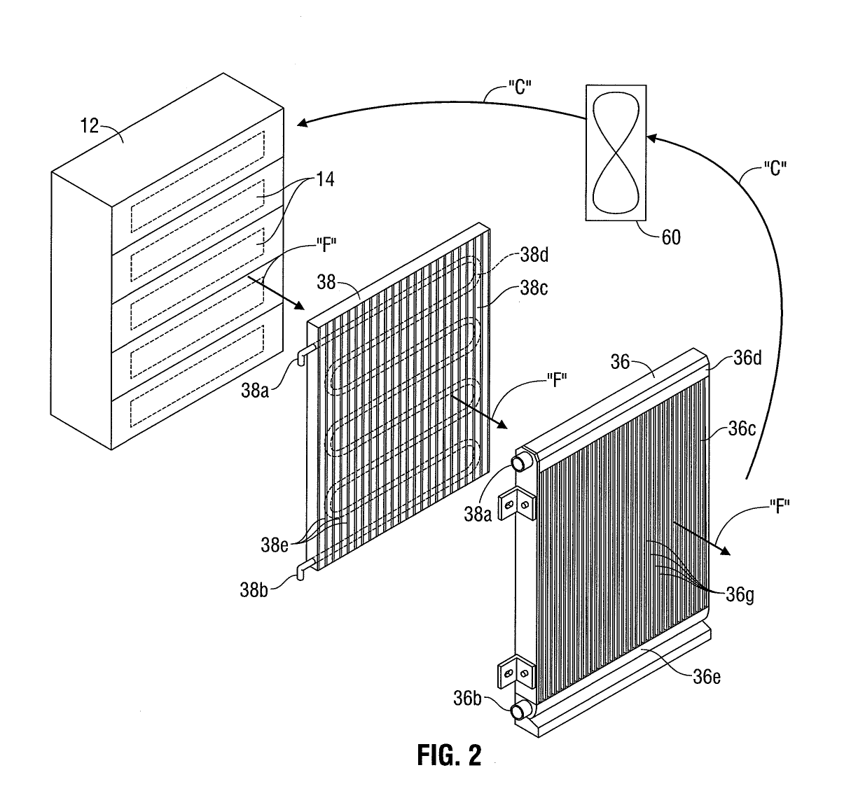

Referring to FIGS. 1 and 2, each of the servers 14 of server rack 12 produces heat during use. The fan 60 creates an airflow path through the servers 14 in the general direction of arrows “F.” Cooling circuit 11 is arranged such that both first and second heat exchangers 36, 38, respectively, are disposed in this airflow path “F,” i.e., in thermal communication with the servers 14. As shown, the second heat exchanger 38 is positioned between server racks 12 and first heat exchanger 36. Depending on the direction of the airflow path “F” through the servers 14 or the airflow paths throughout the data center in general, cooling circuit 11 may be disposed in various different positions relative to server racks 12. For example, first and second heat exchangers 36, 38, respectively, may be arranged in the hot aisle(s) of the data center, in the cool aisle(s) of the data center, in close proximity to the rear of the server rack(s) (e.g., for rear-blow servers), alongside the server rack(s) (e.g., for side-blow servers), above the server rack(s), and/or below the server rack(s).

Further, cooling circuit 11 may be configured for use in modular data pod applications and/or may be adapted for incorporation into existing or new data centers. However, while the orientation of heat exchangers 36, 38 relative to the server rack(s) may be varied depending on the particular configuration of the server racks and/or data center, the relative positioning of heat exchangers 36, 38, i.e., wherein second heat exchanger 38 is positioned in the airflow path between the server rack(s) and first heat exchanger 36, remains the same regardless of the orientation of heat exchangers 36, 38 relative to the server rack(s).

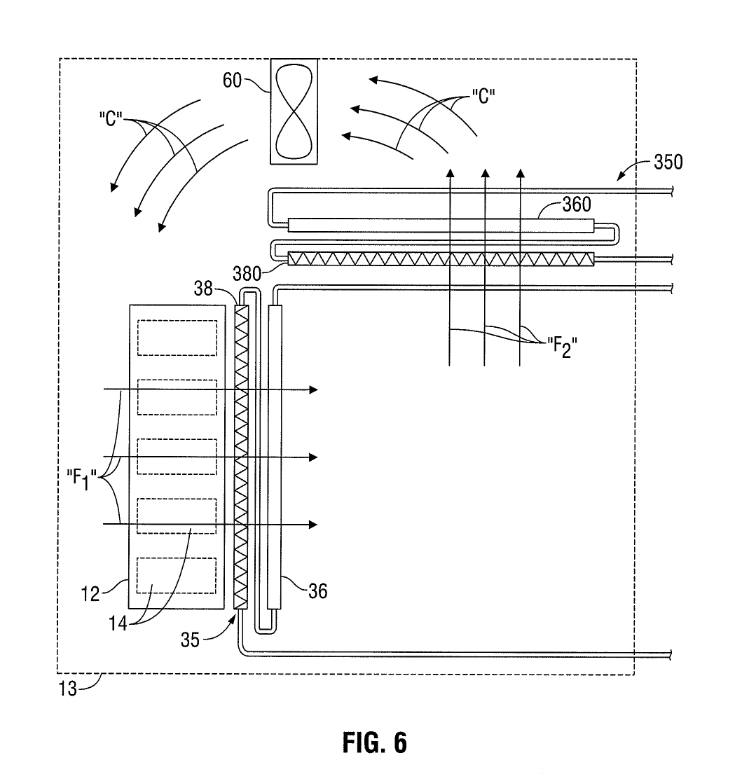

It is also envisioned that multiple cooling circuits and/or cooling circuits having multiple heat exchanger assemblies be provided to work in tandem with one another. For example, as shown in FIG. 6, a first, or primary heat exchanger assembly 35 is positioned adjacent the servers 14 of server rack 12 to cool hot air flowing from the servers 14 in airflow path “F₁,” while a second, or secondary heat exchanger assembly 350 is positioned adjacent the intake side of fan 60 to further cool the hot air as it flows in airflow path “F₂” before the air is re-circulated (as indicated by arrows “C”) through the server rack 12, thus providing “graduated” heat dissipation. The secondary heat exchanger assembly 350 may also provide redundancy in case the primary heat exchanger assembly 35 fails. First and second heat exchanger assemblies 35, 350, respectively, and/or additional heat exchanger assemblies (not shown) may be coupled to the same cooling circuit (in series or in parallel), or independent cooling circuits may be associated with each of the heat exchanger assemblies 35, 350.

Referring again to FIG. 1, in operation, a fluid is circulated through cooling circuit 11, as will be described below, to reject heat produced by the server racks 12, i.e., to reject heat from the hot air flowing out of the back of the server racks 12 along airflow path “F.” With the assistance of fan 60, the resulting cooler air is re-circulated through the enclosure 13, as shown generally by arrows “C,” such that a sufficiently cool operating temperature within the enclosure 13 can be maintained. The fluid circulating through cooling circuit 11 may be R-134a refrigerant, or any other suitable refrigerant or fluorocarbon. For purposes of simplicity and consistency, the fluid flowing through cooling circuit 11 will be referred to as “the refrigerant.”

In operation of some embodiments of the cooling system, the refrigerant exits condenser 30 at a first predetermined temperature (e.g., between about 18° C. (about 65° F.) and about 24° C. (about 75° F.) or, more specifically, about 22° C. (about 72° F.)) and flows through pipe segments 22, 23 to fluid pump 32. Liquid receiver 34 is interdisposed between condenser 30 and fluid pump 32. The liquid receiver 34 ensures that the refrigerant is a liquid as it flows into fluid pump 32, thus helping to limit the pressure within cooling circuit 11. As described below, feedback control assembly 50 uses feedback (readings from temperature sensors 52, 54) to ensure that the temperature of the refrigerant exiting condenser 30 is approximately equal to the first predetermined temperature.

As shown in FIG. 1, fluid pump 32 pumps the liquid refrigerant through pipe segment 24 into fluid input 36a of first heat exchanger 36 at a first predetermined flow rate (e.g., approximately 0.76 l/s (about 12 gpm)). As the liquid refrigerant flows through first heat exchanger 36, the liquid refrigerant absorbs heat from the hot air passing through first heat exchanger 36, i.e., the hot air flowing from the server(s) 14 via airflow path “F,” thus cooling the hot air as it passes through first heat exchanger 36. The heat absorbed by the liquid refrigerant heats the liquid refrigerant to a second predetermined temperature (e.g., between about 24° C. (about 75° F.) and about 32° C. (about 90° F.)) such that a portion of the liquid refrigerant “boils off,” i.e., changes from a liquid to a gas, to form a liquid-gas mixture. More specifically, the liquid refrigerant “boils off” at a rate (e.g., approximately 0.12 l/s (about 1.9 gpm)) that is less that the first predetermined flow rate (e.g., approximately 0.76 l/s (about 12 gpm)) of the refrigerant flowing through the first heat exchanger 36 such that only a portion of the liquid is converted to gas. As a result, a liquid-gas refrigerant mixture exits fluid output 36b of first heat exchanger 36.

The liquid-gas refrigerant mixture exits fluid output 36b of first heat exchanger 36 at the second predetermined temperature (e.g., between about 24° C. (about 75° F.) and about 32° C. (about 90° F.)) and flows through pipe segment 26 into fluid input 38a of second heat exchanger 38. The liquid-gas refrigerant mixture then flows through second heat exchanger 38 where the liquid portion of the refrigerant has a second predetermined flow rate (e.g., approximately 0.64 l/s (about 10.1 gpm)).

Thus, the liquid refrigerant flows through first heat exchanger 36 at the first predetermined rate (e.g., approximately 0.76 l/s (about 12 gpm)). However, as the liquid refrigerant flows through first heat exchanger 36, the liquid refrigerant is “boiled off,” i.e., converted to gas, at a rate of approximately 0.12 l/s (about 1.9 gpm), thus leaving approximately 0.64 l/s (about 10.1 gpm) of liquid refrigerant flowing into second heat exchanger 38.

As the liquid-gas refrigerant mixture flows through second heat exchanger 38, the refrigerant absorbs heat from the hot air passing through second heat exchanger 38, i.e., hot air flowing from server(s) 14 in server rack(s) 12 via airflow path “F,” thus cooling the hot air as it passes through second heat exchanger 38. The heat absorbed by the liquid-gas refrigerant mixture heats the liquid-gas refrigerant mixture as it flows through second heat exchanger 38 such that the remaining liquid of the liquid-gas refrigerant mixture is “boiled off.” More specifically, the liquid portion of the liquid-gas refrigerant mixture is “boiled off” at a second predetermined rate (e.g., approximately 0.64 l/s (about 10.1 gpm)) that is approximately equal to the second predetermined flow rate of the liquid portion of the refrigerant flowing through second heat exchanger 38 such that all of the liquid refrigerant is transformed into gas as the refrigerant flows through second heat exchanger 38. Ultimately, the fully-gaseous refrigerant exits fluid output 38b of second heat exchanger 38 as a superheated gas at a third predetermined temperature (e.g., between about 32° C. (about 90° F.) and about 41° C. (about 105° F.) or, in some embodiments, about 34° C. (about 94° F.)).

The superheated refrigerant gas exits fluid output 38b of second heat exchanger 38 and flows through pipe segment 28 to condenser 30. The condenser 30 is also in fluid communication with a second cooling circuit 40 that includes a cooling fluid supply line 42 and a cooling fluid return line 44. The cooling fluid supply line 42 carries a cooling fluid to the condenser 30, which enables heat transfer from the superheated refrigerant gas flowing through condenser 30 to the cooling fluid flowing through the condenser 30. As a result of the heat transfer, the refrigerant is converted from a superheated gas back to a liquid. The cooling fluid can be any suitable cooling fluid, such as a water solution, a glycol solution (i.e., ethylene/propylene glycol and water), or geothermal water. Alternatively, the superheated refrigerant gas can be cooled by an air-cooled direct-expansion (DX) condenser (not shown), or any other suitable condenser.

Continuing with reference to FIG. 1, feedback control assembly 50 uses feedback (via temperature sensors 52, 54) to ensure that the temperature of the refrigerant exiting condenser 30 is approximately equal to the first predetermined temperature. More specifically, temperature sensors 52, 54 determine the temperature of the refrigerant flowing through pipe sections 22 and 28, respectively, i.e., temperature sensors 52, 54 determine the respective temperature of the refrigerant flowing out of and into condenser 30. These temperatures, in turn, are used to control valve 46, e.g., to increase, decrease, or maintain the flow rate of the cooling fluid flowing through second cooling circuit 40 and condenser 30, thus increasing, decreasing, or maintaining the rate of heat transfer within condenser 30. In other words, by comparing the temperature of the refrigerant at the fluid input and fluid output of the condenser 30, the flow rate of the cooling fluid flowing through the second cooling circuit 40 can be adjusted to achieve a desired output temperature, e.g., the first, predetermined temperature (e.g., approximately 32° C. (about 72° F.)).

Due to the above configuration of cooling circuit 11 and, more particularly, heat exchanger assembly 35, the refrigerant flowing through second heat exchanger 38 has a higher temperature than the refrigerant flowing through first heat exchanger 36. Further, heat exchangers 36, 38 are arranged relative to the airflow path “F” such that relatively hotter air (e.g., the hot flowing from servers 14) passes through second heat exchanger 38, while relatively cooler air (air that has already pass through and been cooled by second heat exchanger 38) passes through first heat exchanger 36. That is, cooling circuit 11 takes advantage of latent heat of vaporization principles by transforming the refrigerant from a liquid to a liquid-gas mixture (as the refrigerant passes through first heat exchanger 36) and from a liquid-gas mixture to a superheated gas (as the refrigerant passes through second heat exchanger 38), such that the relatively hotter refrigerant (flowing through second heat exchanger 38) cools the relatively hotter air initially, while the relatively cooler refrigerant (flowing through first heat exchanger 36) subsequently cools the relatively cooler air. In this manner, greater cooling efficiencies are achieved.

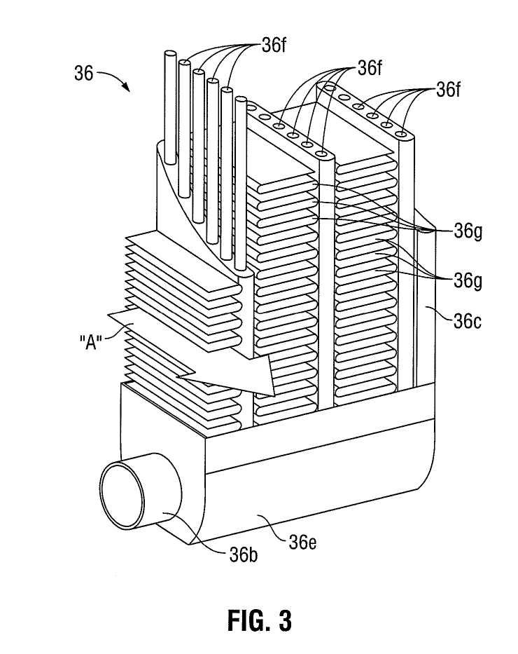

Turning now to FIGS. 2 and 3, first heat exchanger 36 may be a micro-channel heat exchanger 36, although other suitable heat exchangers are also contemplated. Micro-channel heat exchanger 36 generally includes a fluid input 36a, a fluid output 36b, and a body portion 36c. Body portion 36c includes an upper horizontal tube or conduit 36d fluidly coupled to fluid input 36a, a lower horizontal conduit 36e fluidly coupled to fluid output 36b, a plurality of spaced-apart rows of micro-channels 36f interconnecting upper and lower horizontal conduits 36d, 36e, respectively, and a plurality of stacks of fins 36g disposed between the rows of micro-channels 36f.

In use, fluid flows into upper horizontal conduit 36d via fluid input 36a, down the plurality of micro-channels 36f into lower horizontal conduit 36e, and out fluid output 36b. Fins 36g direct air flow through body portion 36c, as generally indicated by arrow “A,” such that substantially all of the exterior surface area of each of micro-channels 36f is in thermal communication with the air flowing through body portion 36c. As such, micro-channel heat exchanger 36 achieves efficient heat transfer between the air flowing through body portion 36c and the fluid flowing through micro-channels 36f, while also reducing both fluid and air pressure drops across body portion 36c. Micro-channel heat exchanger 36 is also spatially efficient, having a thickness of about 2.86 cm (about 1.125 inches) and height and width generally approximating that of a typical server rack, i.e., a height of between about 196 cm and about 213 cm (between about 77 inches and 84 inches) and a width between about 76 cm and about 81 cm (between about 30 inches and about 32 inches), although other dimensions are contemplated, depending on the particular use.

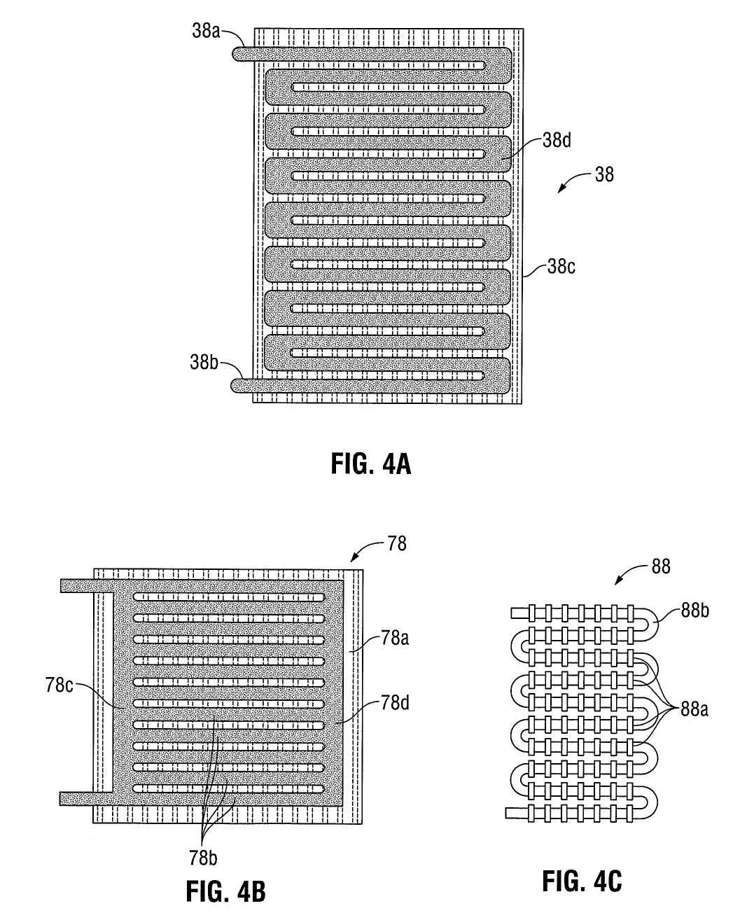

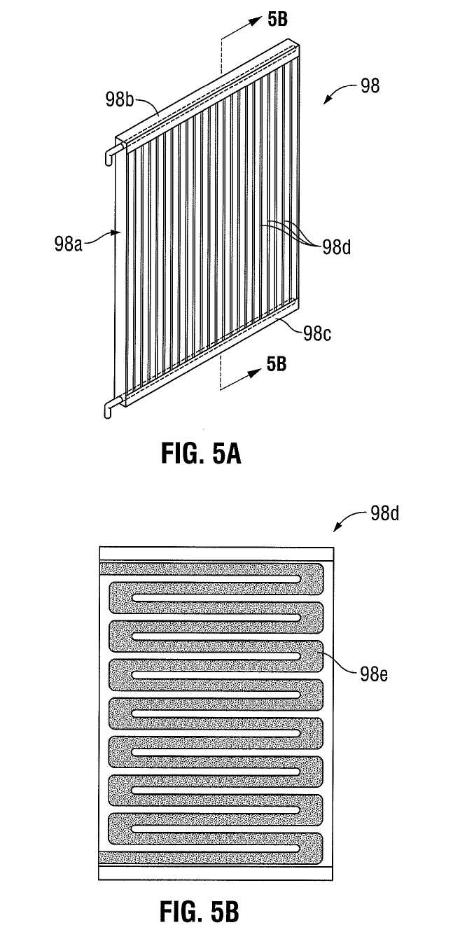

Referring to FIG. 2, in conjunction with FIG. 4A, second heat exchanger 38 may be a serpentine heat exchanger 38, although other suitable heat exchangers are also contemplated, e.g., a flat-plate heat exchanger 98 (FIGS. 5A-5B). Serpentine heat exchanger 38, as best shown in FIG. 4A, includes a fluid input 38a, a body portion 38c having a serpentine-shaped conduit 38d disposed therein, a fluid output 38b, and a plurality of spaced-apart fins 38e disposed about and in generally perpendicular orientation (although other configurations are contemplated) relative to serpentine-shaped conduit 38d.

During operation, fluid flows into conduit 38d via fluid input 38a, through serpentine-shaped conduit 38d, and out of the conduit 38d via fluid output 38b. Fins 38e direct air flow through body portion 38c in a generally perpendicular direction relative to the direction of fluid flow through conduit 38d such that the air flowing through body portion 38c substantially surrounds conduit 38d, thus enabling heat exchanger from the air flowing through body portion 38c and the fluid flowing through conduit 38d. Further, serpentine heat exchanger 38 is spatially efficient, having a thickness of about 13 mm (about 0.5 inches) and height and width generally approximating that of a typical server rack, i.e., a height of between about 196 cm and about 213 cm (between about 77 inches and 84 inches) and a width between about 76 cm and about 81 cm (between about 30 inches and about 32 inches), although other dimensions are contemplated, depending on the particular use.

FIG. 4B shows another embodiment of a serpentine heat exchanger 78. Serpentine heat exchanger 78 is similar to heat exchanger 38 (FIG. 2) except that, rather than having a serpentine-shaped conduit 38d (FIG. 4A), body portion 78a includes a plurality of horizontal conduits 78b interconnecting base conduits 78c and 78d. Similar to the serpentine-shaped conduit 38d (FIG. 4A), the arrangement of horizontal conduits 78b and base conduits 78c, 78d provides substantial surface area of conduits 78b, 78c, 78d to facilitate heat transfer between air passing through body portion 78a of heat exchanger 78 and fluid flowing through conduits 78b, 78c, 78d.

Turning to FIG. 4C, another embodiment of a serpentine heat exchanger 88 is shown. Serpentine heat exchanger 88 is similar to serpentine heat exchanger 38 (FIG. 2) except that, rather than providing a body portion 38c (FIG. 4A) having elongated fins 38e (FIG. 4A), serpentine heat exchanger 88 includes a plurality of individual fins 88a disposed along serpentine-shaped conduit 88b that are configured to direct airflow in a generally perpendicular direction relative to serpentine-shaped conduit 88b, thus facilitating heat transfer from the air flowing about serpentine-shaped conduit 88b to the fluid flowing through serpentine-shaped conduit 88b.

FIGS. 5A-5B illustrate a flat-plate heat exchanger 98, which is another example embodiment of the second heat exchanger. Flat-plate heat exchanger 98 includes a body portion 98a having a plurality of elongated, spaced-apart plates 98d. Plates 98d each define a flat configuration and are positioned substantially parallel relative to one another. However, it is also envisioned that plates 98d be angled relative to one another and/or that plates 98d define curved or other configurations, depending on the particular purpose. Each plate 98d includes an internal conduit 98e, or conduit system, that facilitates heat transfer between the air flowing between plates 98b and the fluid flowing through internal conduits 98e. Flat-plate heat exchanger 98 may be dimensioned similarly to heat exchanger 38 (FIG. 2)

Flat-plate heat exchanger 98 includes an upper base conduit 98b fluidly coupled to the fluid input of heat exchanger 98 and a lower base conduit 98c fluidly coupled to the fluid output of heat exchanger 98. Upper and lower base conduits 98b, 98c, respectively, are interconnected by the internal conduits 98e of each of the plates 98d such that the refrigerant can flow into upper base conduit 98b via the fluid input, through the internal conduits 98e of the plates 98d and, ultimately, into lower base conduit 98c for exiting heat exchanger 98 via the fluid output. As best shown in FIG. 5B, the internal conduit 98e of each plate 98b may define a serpentine-shaped configuration, or any other suitable configuration. It is also envisioned that each plate 98b include a system, or network of conduits 98e (e.g., similar to the configuration shown in FIG. 4B).

In operation, this arrangement—where plates 98b each include a conduit 98e (or conduits) disposed therein—provides substantial surface area (the surface area of plates 98b) to facilitate heat transfer from air or another fluid passing through body portion 98a of heat exchanger 98 to fluid flowing through conduits 98e.

In some embodiments, where second heat exchanger 38 is a serpentine or flat-plate heat exchanger and where first heat exchanger 36 is a micro-channel heat exchanger, the second heat exchanger functions as a diffuser that facilitates greater diffusion of air across a greater percentage of the surface area of the micro-channel heat exchanger, thus increasing the cooling efficiency of the system. The serpentine or flat-plate heat exchanger 38 and micro-channel heat exchanger 36 also cooperate to define a reduced-area configuration due to their minimal thickness dimensions, as described above.

Further, this particular configuration of first and second heat exchangers 36, 38, respectively, provides for tiered or graduated cooling, wherein air in airflow path “F” is initially cooled via the serpentine heat exchanger 38, before being cooled further by the micro-channel heat exchanger 36. However, although cooling system 10 is particularly advantageous when used in conjunction with serpentine (or flat-plate) and micro-channel heat exchangers 38, 36, respectively, it is also envisioned that other suitable heat exchangers or combinations of heat exchangers may be used in conjunction with cooling circuit 11, depending on a particular purpose. Further, it is envisioned that the above-described advantages of the serpentine (or flat-plate) and micro-channel heat exchangers 38, 36, respectively, may likewise be realized through the use of different types and/or combinations of heat exchangers.

The cooling capability of an exemplary cooling circuit in accordance with the present disclosure is described in mathematical terms as follows. The exemplary cooling circuit includes a first heat exchanger and a second heat exchanger, each having general height and width dimensions of about 213 cm (about 84 inches) and about 76 cm (about 30 inches), respectively. The refrigerant, R134a, flowing through the cooling circuit has a molecular weight of 102.03, or about 1020 kg/m³ (about 8.51 lbs/gallon). The latent heat of vaporization of R134a is about 217 kJ/kg (about 92.82 btu/lb).

As mentioned above, the fluid pump 32 pumps the refrigerant into the first heat exchanger 36 at a rate of about 0.76 l/s (about 12 gpm). Thus, the mass flow rate of the refrigerant is about 0.77 kg/s (about (102.12 lbs/min). Using the latent heat of vaporization of R134a, the compression work is equal to about 166.7 kJ/s (about 9,479 btu/min). Extrapolating this out for a one hour period provides about 600,052 kJ/hr (about 568,740 btu/hr). Thus, given that 1 kW equals about 3603 kJ/hr (or about 3415 btu/hr), this cooling circuit is capable of rejecting a heat load of approximately 166.5 kW.

Although this particular embodiment of a cooling circuit can reject a heat load of approximately 166 kW, the heat rejection capabilities of the cooling circuit provided in accordance with the present disclosure can be scaled up or down to accommodate the heat load output of the particular computer server(s) (or electronic device(s)) to be cooled. That is, the above-calculation is meant for exemplary purposes only, as it is envisioned and within the scope of the present disclosure that the specific configuration of the presently-disclosed cooling circuit may be adapted (or scaled) for cooling different electronic equipment having different heat load outputs, dimensions, etc. and, thus, that the values used in the calculations above may vary depending on the particular purpose.

From the foregoing and with reference to the various figure drawings, those skilled in the art will appreciate that certain modifications can be made to the present disclosure without departing from the scope of the same. While several embodiments of the disclosure have been shown in the drawings, it is not intended that the disclosure be limited thereto, as it is intended that the disclosure be as broad in scope as the art will allow and that the specification be read likewise. Therefore, the above description should not be construed as limiting, but merely as exemplifications of particular embodiments. Those skilled in the art will envision other modifications within the scope and spirit of the claims appended hereto.

What is claimed is:

1. A system for cooling electronic equipment, comprising:
a first heat exchanger having a fluid input and a fluid output, the first heat exchanger configured to be disposed in an airflow in thermal communication with electronic equipment, the fluid input of the first heat exchanger configured to receive a cooling fluid at a first temperature, the first heat exchanger configured to enable heat transfer from the airflow to the cooling fluid to heat the cooling fluid to a second temperature;
a second heat exchanger having a fluid input and a fluid output, the fluid input of the second heat exchanger in fluid communication with the fluid output of the first heat exchanger, the second heat exchanger configured to be disposed in the airflow between the first heat exchanger and the electronic equipment, the fluid input of the second heat exchanger configured to receive the cooling fluid at the second temperature from the fluid output of the first heat exchanger, the second heat exchanger enabling heat transfer from the airflow to the cooling fluid to heat the cooling fluid to a third temperature; and
a condenser having a fluid input and a fluid output, the fluid input of the condenser in fluid communication with the fluid output of the second heat exchanger and the fluid output of the condenser in fluid communication with the fluid input of the first heat exchanger, the fluid input of the condenser receiving the cooling fluid at the third temperature from the fluid output of the second heat exchanger, the condenser enabling heat transfer from the cooling fluid to a cooling source to cool the cooling fluid to the first temperature.

2. The system of claim 1, wherein the first heat exchanger is a micro-channel heat exchanger.

3. The system of claim 1, wherein the second heat exchanger is a flat-plate heat exchanger.

4. The system of claim 1, wherein the second heat exchanger is a serpentine heat exchanger.

5. The system of claim 1, wherein the second heat exchanger diffuses the airflow across the first heat exchanger.

6. The system of claim 1, wherein the condenser transforms the cooling fluid from a gas to a liquid.

7. The system of claim 1, wherein the first heat exchanger transforms the cooling fluid from a liquid to a liquid-gas mixture.

8. The system of claim 1, wherein the second heat exchanger transforms the cooling fluid from a liquid-gas mixture to a gas.

9. The system of claim 1, wherein the first temperature is between about 18° Celsius and about 24° Celsius, wherein the second temperature is between about 24° Celsius and about 32° Celsius, and wherein the third temperature is between about 32° Celsius and about 41° Celsius.

10. A method of cooling electronic equipment, comprising:
passing a first cooling fluid through a first heat exchanger disposed in an airflow in thermal communication with electronic equipment to transform the first cooling fluid from a liquid to a liquid-gas mixture;
passing the first cooling fluid through a second heat exchanger disposed in the airflow between the first heat exchanger and the electronic equipment to transform the first cooling fluid from the liquid-gas mixture to a gas; and
condensing the first cooling fluid from a gas to a liquid by enabling heat transfer from the first cooling fluid to a second cooling fluid flowing through a cooling circuit.

11. The method of claim 10, wherein the first heat exchanger is a micro-channel heat exchanger.

12. The method of claim 10, wherein the second heat exchanger is a flat-plate heat exchanger.

13. The method of claim 10, wherein the second heat exchanger is a serpentine heat exchanger.

14. The method of claim 10, wherein the second heat exchanger diffuses the airflow across the first heat exchanger.

15. The method of claim 10, wherein the step of passing the cooling fluid through the first heat exchanger includes heating the cooling fluid from a first temperature to a second temperature, the step of passing the cooling fluid through the second heat exchanger includes heating the cooling fluid from the second temperature to a third temperature, and the step of condensing the cooling fluid includes cooling the cooling fluid from the third temperature to the first temperature.

16. A heat exchanger assembly for cooling electronic equipment, comprising:
a first heat exchanger configured to be disposed in thermal communication with electronic equipment, the first heat exchanger configured to receive cooling fluid in a liquid phase, the first heat exchanger configured to transform the cooling fluid from the liquid phase to a liquid-gas mixture phase; and
a second heat exchanger in thermal communication with the electronic equipment, the second heat exchanger configured to receive the cooling fluid in the liquid-gas mixture phase, the second heat exchanger configured to transform the cooling fluid from the liquid-gas mixture phase to a gas phase.

17. The heat exchanger assembly of claim 16, wherein the first heat exchanger and the second heat exchanger are configured to be disposed in an airflow path.

18. The heat exchanger assembly of claim 17, wherein the second heat exchanger is configured to be disposed in the airflow path upstream from the first heat exchanger.

19. The heat exchanger assembly of claim 18, wherein the second heat exchanger diffuses the airflow across the first heat exchanger.

20. The heat exchanger assembly of claim 16, wherein the first heat exchanger is a micro-channel heat exchanger and the second heat exchanger is a flat-plate heat exchanger or a serpentine heat exchanger.
